(19) United States
(12) Patent Application Publication
(10) Pub. No.: US 2012/0211083 A1
(43) Pub. Date: Aug. 23, 2012

(54) METHOD FOR MANUFACTURING ORGANIC THIN FILM SOLAR CELL MODULE

(76) Inventors: Takahiro Seike, Tsukuba-shi (JP); Toshihiro Ohnishi, Tsukuba-shi (JP)

(21) Appl. No.: 13/504,018

(22) PCT Filed: Oct. 26, 2010
(86) PCT No.: PCT/JP2010/068959

§ 371 Date: Apr. 25, 2012

(51) Int. Cl. H01L 51/42; H01L 51/48

(52) U.S. Cl. 136/263; 438/77; 257/E51.012

(57) ABSTRACT

Provided is a method for manufacturing an organic thin film solar cell module that can be manufactured by simple steps. As the method for manufacturing an organic thin film solar cell module, the method for manufacturing an organic thin film solar cell module in which a plurality of organic photovoltaic cells (100A1) and (100A2) comprising a pair of electrodes comprising a first electrode (20) and a second electrode (70) and an active layer (50) that is placed between the pair of electrodes are arranged on a substrate (10), the method comprises: forming the first electrodes on the substrate; and forming a lyophobic pattern (30a) on a part of each of the first electrodes.

### TECHNICAL FIELD

The present invention relates to a method for manufacturing an organic thin film solar cell module in which a plurality of organic photovoltaic cells are integrated on the same substrate.

### BACKGROUND ART

An organic thin film solar cell module is generally manufactured by a method for manufacturing comprising: (1) preparing a substrate; (2) forming a first electrode on the substrate; (3) forming a first charge transport layer on the first electrode; (4) forming an active layer on the first charge transport layer; (5) forming a second charge transport layer on the active layer; and (6) forming a second electrode on the second charge transport layer.

In other words, the organic thin film solar cell module is manufactured by sequentially film forming functional layers of a plurality of layers such as a charge transport layer and an active layer. Each functional layer is patterned in a desired shape by any preferable patterning step depending on its material and the like.

Conventionally, for forming a desired shape of the active layer, (i) a direct patterning process such as a printing method has been performed or (ii) a wet etching process, a dry etching process, a laser patterning process or a mechanical patterning process in which the desired shape is patterned by removing unnecessary regions after film forming has been performed other than the film forming step.

As the direct patterning process used for a thin film forming step of the organic thin film solar cell (the organic photovoltaic cell), printing methods comprising a gravure printing method, a screen printing method and an ink-jet printing method have been known (refer to Non Patent Document 1).

As the laser patterning process in the steps for manufacturing the organic thin film solar cell, an example in which a layer of the active layer (MDMO-PPV: PCBM layer) is isolated by using Nd:YAG laser having a wavelength of 532 nm has been known (refer to Non Patent Document 2).

### NON PATENT DOCUMENT

Non Patent Document 1: Solar Energy Materials and Solar Cells, 93, (2009) 394-412
Non Patent Document 2: Journal of Materials Research., 20, (2005) 3224

### DISCLOSURE OF INVENTION

### Problem to be Solved by the Invention

However, when, for example, a coating method is used as the direct patterning process, applied coating liquid may be exuded and protruded to an undesired region. As a result, operation failure may occur because organic photovoltaic cells adjacent each other may electrically short. When a wet etching process, a dry etching process or a laser patterning process is used, not only does the number of steps increase, but also large-sized and expensive equipment such as a vacuum system is required.

The inventors of the present invention have eagerly investigated an organic thin film solar cell module and a method for manufacturing the same. As a result, the inventors have found that the problem can be solved by providing a lyophobic pattern and have accomplished the present invention.

In other words, the present invention provides an organic thin film solar cell module and a method for manufacturing the same described below.

[1] A method for manufacturing an organic thin film solar cell module in which a plurality of organic photovoltaic cells comprising a pair of electrodes comprising a first electrode and a second electrode and an active layer that is placed between the pair of electrodes are arranged on a substrate, the method comprising the steps of:

forming the first electrodes on the substrate; and

forming a lyophobic pattern on a part of each of the first electrodes.

[2] A method for manufacturing an organic thin film solar cell module in which a plurality of organic photovoltaic cells comprising a pair of electrodes comprising a first electrode and a second electrode and an active layer that is placed between the pair of electrodes are arranged on a substrate, the method comprising the steps of:

forming the first electrodes on the substrate; and

forming a lyophobic pattern on the substrate out of the first electrodes.

[3] The method for manufacturing an organic thin film solar cell module according to above [1] or [2], wherein the step of forming the lyophobic pattern comprises:

forming a lyophobic region over an entire surface of the substrate on which the first electrodes are formed; and

forming a mask pattern covering over a part of the substrate on which the first electrodes are formed, performing lyophilic treatment using the mask pattern as a mask to the entire surface of the substrate on which the first electrodes are formed, and removing the mask pattern, thereby forming the lyophobic pattern.

[4] A method for manufacturing an organic thin film solar cell module, the method comprising the steps of:

forming a plurality of first electrodes on a substrate;

forming a lyophobic region on an entire surface of the substrate on which the first electrodes are formed;

forming a lyophobic pattern by forming a mask pattern covering over a part of the substrate on which the first electrodes are formed, performing lyophilic treatment using the mask pattern as a mask to the entire surface of the substrate on which the first electrodes are formed, and removing the mask pattern;

forming a first charge transport layer comprising a first exposure part exposing the lyophobic pattern, an active layer covering over the first charge transport layer, and a second charge transport layer covering over the active layer, by applying a coating liquid that is repelled by the lyophobic pattern on the entire surface of the substrate on which the lyophobic pattern is formed;

forming a second exposure region in which a part of the first electrodes located out of the lyophobic pattern is exposed, configured to pass through the second charge transport layer, the active layer, and the first charge transport layer;

forming a second electrode by applying a coating liquid, the second electrode covering over the second charge transport layer, embedding the second exposure region, and not covering the lyophobic pattern; and

isolating a plurality of organic photovoltaic cells by forming a third exposure region in which a part of the first charge transport layer located out of the lyophobic pattern is exposed, configured to pass through the second electrode, the second charge transport layer, and the active layer.

[5] The method for manufacturing an organic thin film solar cell module according to above [4], wherein the step of forming the lyophobic pattern comprises removing the lyophobic region from the surface of the first electrodes by lyophilic treatment to the entire surface of the substrate using difference between bond strength between a material comprised in the substrate and a material comprised in the lyophobic region and bond strength between a material comprised in the first electrodes and a material comprised in the lyophobic region, and leaving the material comprised in the lyophobic region in a region where the first electrodes are not formed in the surface of the substrate, thus forming the lyophobic pattern.
[6] The method for manufacturing an organic thin film solar cell module according to any one of above [1] to [5], wherein the step of forming the lyophobic pattern comprises forming the lyophobic pattern using a coupling agent comprising one metal selected from the group consisting of silicon, aluminum, and titanium.
[7] The method for manufacturing an organic thin film solar cell module according to any one of above [1] to [5], wherein the step of forming the lyophobic pattern comprises forming the lyophobic pattern using a material comprising a thiol compound.
[8] The method for manufacturing an organic thin film solar cell module according to any one of above [1] to [5], wherein the step of forming the lyophobic pattern comprises forming the lyophobic pattern using a material comprising fluorine.
[9] The method for manufacturing an organic thin film solar cell module according to above [8], wherein the step of forming the lyophobic pattern comprises forming the lyophobic pattern by steaming treatment using one or more selected from the group consisting of CF₄, NF₃, and a mixture of CF₄ and methanol.
[10] An organic thin film solar cell module that is manufactured by the method for manufacturing according to above any one of [1] to [9].

### BRIEF DESCRIPTION OF DRAWINGS

FIG. 1 is a schematic cross-sectional view (1) illustrating a method for manufacturing according to a first embodiment.

FIG. 2 is a schematic cross-sectional view (2) illustrating the method for manufacturing according to the first embodiment.

FIG. 3 is a schematic cross-sectional view (3) illustrating the method for manufacturing according to the first embodiment.

FIG. 4 is a schematic cross-sectional view (4) illustrating the method for manufacturing according to the first embodiment.

FIG. 5 is a schematic cross-sectional view (5) illustrating the method for manufacturing according to the first embodiment.

FIG. 6 is a schematic cross-sectional view (6) illustrating the method for manufacturing according to the first embodiment.

FIG. 7 is a schematic cross-sectional view (7) illustrating the method for manufacturing according to the first embodiment.

FIG. 8 is a schematic cross-sectional view (8) illustrating the method for manufacturing according to the first embodiment.

FIG. 9 is a schematic cross-sectional view (9) illustrating the method for manufacturing according to the first embodiment.

FIG. 10 is a schematic cross-sectional view (1) illustrating a method for manufacturing according to a second embodiment.

FIG. 11 is a schematic cross-sectional view (2) illustrating the method for manufacturing according to the second embodiment.

FIG. 12 is a schematic cross-sectional view (3) illustrating the method for manufacturing according to the second embodiment.

FIG. 13 is a schematic cross-sectional view (4) illustrating the method for manufacturing according to the second embodiment.

FIG. 14 is a schematic cross-sectional view (5) illustrating the method for manufacturing according to the second embodiment.

FIG. 15 is a schematic cross-sectional view (6) illustrating the method for manufacturing according to the second embodiment.

FIG. 16 is a schematic cross-sectional view (7) illustrating the method for manufacturing according to the second embodiment.

FIG. 17 is a schematic cross-sectional view (8) illustrating the method for manufacturing according to the second embodiment.

FIG. 18 is a schematic cross-sectional view (9) illustrating the method for manufacturing according to the second embodiment.

### EXPLANATIONS OF LETTERS OR NUMERALS

10 substrate
10A electrode forming region
10B electrode non-forming region
20 first electrode
30 lyophobic region
30a lyophobic pattern
40 first charge transport layer
50 active layer
60 second charge transport layer
70 second electrode
70a contact
100A1 first cell
100A2 second cell
100B region between cells
R lyophilic treatment
X first exposure region
Y second exposure region
Z third exposure region

### DESCRIPTION OF EMBODIMENTS

<Organic Thin Film Solar Cell Module>

An organic thin film solar cell module according to the present invention may basically form a module structure similar to an existing solar cell module. The organic thin film solar cell module generally forms a structure in which a plurality of organic photovoltaic cells (cells) are configured on a substrate (a supporting substrate) made of a metal, a ceramic or the like, and the organic photovoltaic cells are covered with a filling resin, protection glass or the like to take light from a opposite side of the substrate. However, a structure in which a transparent material such as reinforced glass is used for the substrate and light is taken from a side of the transparent substrate by configuring the organic photovoltaic cells on the transparent substrate may be formed.

Examples of structure of the organic thin film solar cell module are known as module structures referred to as a superstrate type, a substrate type, a potting type; a substrate-integrated module structure used for an amorphous silicon solar cell and the like.

The structure of the organic thin film solar cell module according to the present invention may be adequately selected from these module structures depending on intended use, and place and environment of use.

A representative superstrate type or substrate type module structure forms a structure in which the organic photovoltaic cells are arranged at constant intervals between the substrates whose one side or both sides is or are transparent and to which antireflection treatment is applied; the adjacent organic photovoltaic cells are connected with each other by a contact electrode (an embedded electrode), a metal lead, a flexible wiring or the like; a collecting electrode is arranged in an outer edge part; and generated electric power is taken out to outside.

In order to protect the organic photovoltaic cell and to improve power collection efficiency, various kinds of plastic materials such as ethylene-vinyl acetate (EVA) may be used depending on purposes in the form of a film or a filling resin between the substrate and the organic photovoltaic cells. When the module is used in places where its surface is not required to be covered with a hard material, such as a place where impact from the outside seldom occurs, one side of the substrate may be eliminated by adding a protection function in a manner that a surface protection layer is constituted by a transparent plastic film and the filling resin is cured. In order to secure inner sealing and rigidity of the module, circumference of the substrate is sandwiched to fix with a frame made by a metal and clearance between the substrate and the frame is tightly sealed by a sealing material. When a flexible material are used in the organic photovoltaic cell itself, the substrate, the filling material and the sealing material, the organic photovoltaic cell can be constituted on a curved surface.

In the case of a solar cell module using a flexible support body such as a polymer film, the solar cell module may be manufactured by sequentially forming the photovoltaic cells on the roll-type support body with pulling out the support body and cutting the support body in a desired size, and then sealing the circumference region by a material having flexibility and a moisture-proof property.

A module structure referred to as “SCAF” described in Solar Energy Materials and Solar Cells, 48, p 383-391 can also be used. The solar cell module using a flexible support body may be used by fixing the module on a curved glass and the like with an adhesive.

Hereinafter, the present invention is described in detail with reference to the drawings. In the organic thin film solar cell module having the above-described constitution, descriptions of exterior parts such as a frame and a protection member are omitted because these are not the essentials of the present invention, and the organic photovoltaic cell and the method for manufacturing the same are mainly described.

In the following description, each drawing only schematically illustrates shapes, sizes and locations of constituent cells in such a degree that the present invention can be understood. Therefore, the present invention is not particularly limited by this description. In addition, the same reference letters or numerals may be assigned and illustrated to a similar constituent and redundant description thereof may be omitted.

### First Embodiment

A method for manufacturing an organic thin film solar cell module according to the first embodiment in which a plurality of organic photovoltaic cells comprising a pair of electrodes comprising a first electrode and a second electrode and an active layer that is placed between the pair of electrodes are arranged on a substrate comprises: forming the first electrodes on the substrate; and forming a lyophobic pattern on a part of each of the electrodes.

More specifically, a method for manufacturing an organic thin film solar cell module according to the first embodiment comprises: forming a plurality of first electrodes on a substrate; forming a lyophobic region on the entire surface of the substrate on which the first electrodes are formed; forming a mask pattern covering over a part of the substrate on which the first electrodes are provided, performing lyophilic treatment using the mask pattern as a mask to the entire surface of the substrate on which the first electrodes are formed, and forming a lyophobic pattern by removing the mask pattern; forming a first charge transport layer comprising a first exposure region exposing the lyophobic pattern, an active layer covering over the first charge transport layer and a second charge transport layer covering over the active layer by applying a coating liquid that is repelled by the lyophobic pattern on the entire surface of the substrate on which the lyophobic pattern is formed; forming a second exposure region in which a part of the first electrodes located out of the lyophobic pattern is exposed by, configured to pass through the second charge transport layer, the active layer and the first charge transport layer; forming a second electrode that covers over the second charge transport layer, embeds the second exposure region and does not cover the lyophobic pattern by applying the coating liquid; and forming a third exposure region in which a part of the first charge transport layer located out of the lyophobic pattern is exposed, configured to pass through the second electrode, the second charge transport layer and the active layer to isolate a plurality of organic photovoltaic cells.

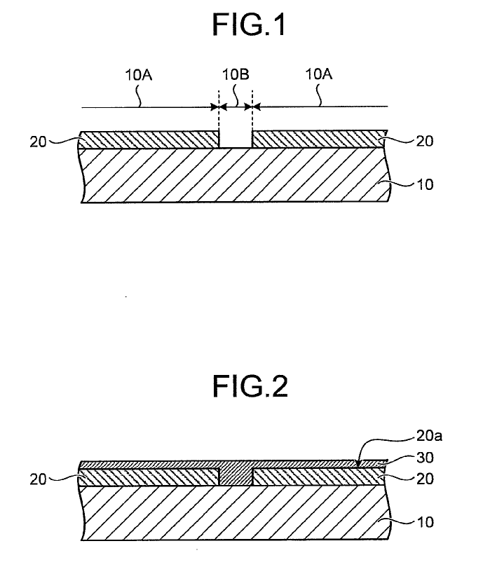

With reference to from FIG. 1 to FIG. 9, the method for manufacturing the organic thin film solar cell module according to the first embodiment is specifically described.

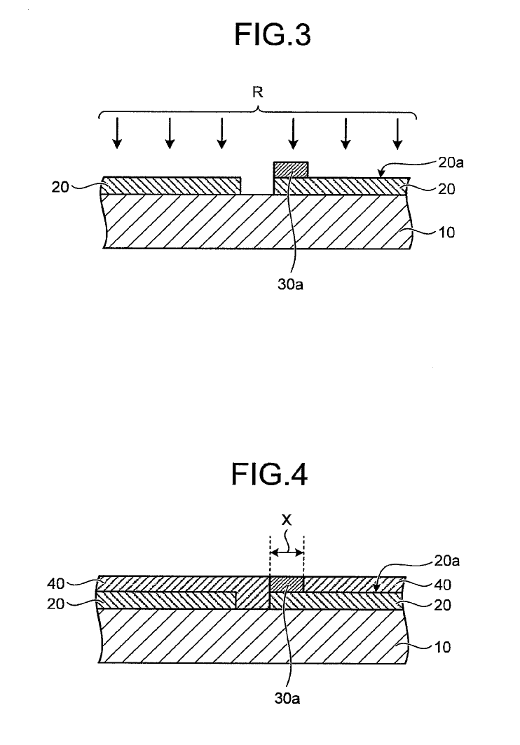

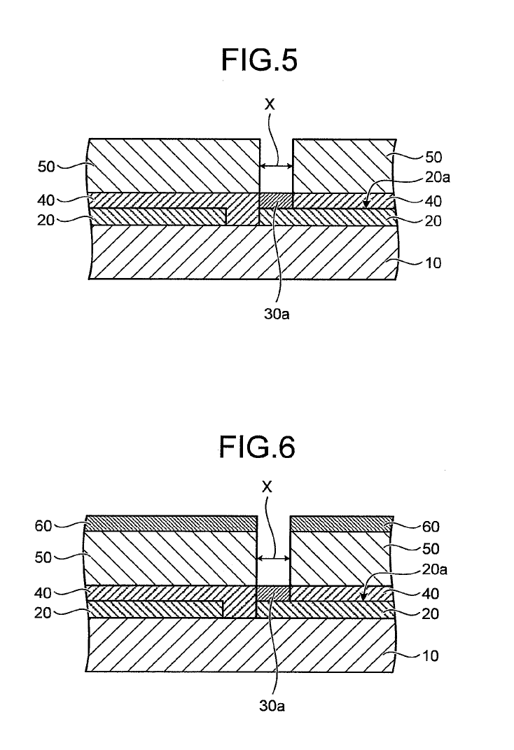

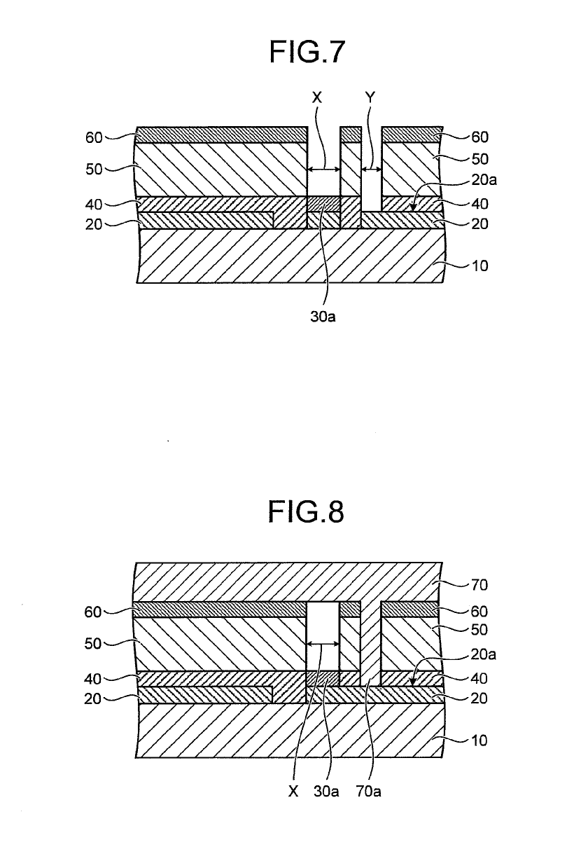

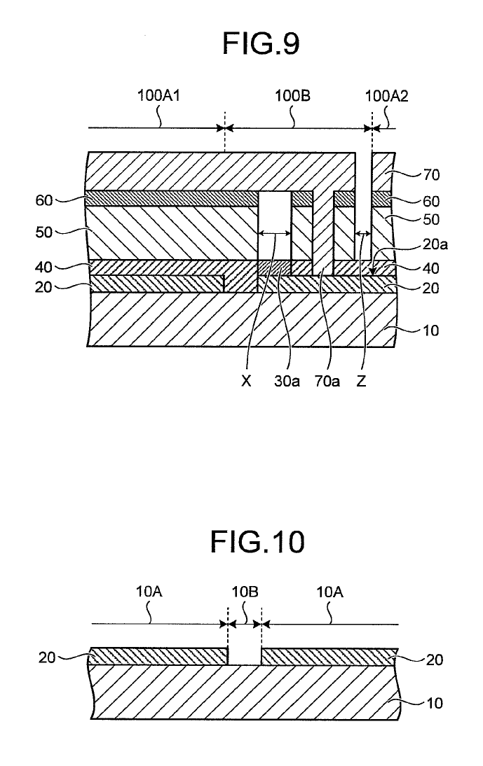

FIG. 1 is a schematic cross-sectional view (1) illustrating the method for manufacturing according to the first embodiment. FIG. 2 is a schematic cross-sectional view (2) illustrating the method for manufacturing according to the first embodiment. FIG. 3 is a schematic cross-sectional view (3) illustrating the method for manufacturing according to the first embodiment. FIG. 4 is a schematic cross-sectional view (4) illustrating the method for manufacturing according to the first embodiment. FIG. 5 is a schematic cross-sectional view (5) illustrating the method for manufacturing according to the first embodiment. FIG. 6 is a schematic cross-sectional view (6) illustrating the method for manufacturing according to the first embodiment. FIG. 7 is a schematic cross-sectional view (7) illustrating the method for manufacturing according to the first embodiment. FIG. 8 is a schematic cross-sectional view (8) illustrating the method for manufacturing according to the first embodiment. FIG. 9 is a schematic cross-sectional view (9) illustrating the method for manufacturing according to the first embodiment.

As shown in FIG. 1, a substrate 10 is firstly prepared. The substrate 10 is a planar substrate having two main surfaces facing each other. For preparing the substrate 10, a substrate in which a conductive material thin film being possible to be a material for an electrode such as indium tin oxide (may be referred to as ITO) is previously provided on one main surface of the substrate 10 may be prepared.

When the conductive material thin film is not provided on the substrate 10, the conductive material thin film is formed on one main surface of the substrate 10 by any preferable method. Subsequently, the conductive material thin film is patterned. At this patterning, an electrode forming region 10A and an electrode non-forming region 10B located out of the electrode forming region 10A are previously determined. The conductive material thin film is patterned by any preferable method such as a photolithography step and an etching step to form a first electrode 20 that is formed by a plurality of patterns electrically isolated each other in the electrode forming region 10A. By this step, a part of the main surface of the substrate 10 is exposed in the electrode non-forming region 10B where the first electrode 20 is not formed.

As shown in FIG. 2, a lyophobic region 30 having lyophobicity is formed on the entire surface of the substrate 10 on which the first electrode 20 comprising the surface 20a of the first electrode 20 is formed.

As shown in FIG. 3, a mask pattern covering a part on the substrate 10 on which the first electrode 20 is provided is formed (not illustrated). The entire surface of the substrate 10 on which the first electrode 20 is formed is made lyophilic by lyophilic treatment R using the mask pattern as a mask.

The lyophilic treatment R may be preferably plasma treatment, UV ozone treatment or corona discharge treatment in accordance with ordinary procedures.

Subsequently, the mask pattern is removed to form a lyophobic pattern 30a. Examples of steps of forming the lyophobic pattern 30a may include a step in which the lyophobic region 30 is firstly formed using a coupling agent and then the lyophobic pattern 30a is formed, and a step in which the lyophobic region 30 is firstly formed using a material comprising a thiol compound and then the lyophobic pattern 30a is formed.

Examples of coupling agents comprising Si as a metal may include vinyl trichloro silane, vinyl trimethoxy silane, vinyl triethoxy silane, 2-(3,4-epoxycyclohexyl) ethyl trimethoxy silane, 3-glycidoxypropyl trimethoxy silane, 3-glycidoxypropyl methyl diethoxy silane, 3-glycidoxypropyl triethoxy silane, p-styryl trimethoxy silane, 3-methacryloxypropyl methyl dimethoxy silane, 3-methacryloxypropyl trimethoxy silane, 3-methacryloxypropyl methyl diethoxy silane, 3-methacryloxypropyl triethoxy silane, 3-acryloxypropyl trimethoxy silane, N-2-(aminoethyl)-3-aminopropyl methyl dimethoxy silane, N-2-(aminoethyl)-3-aminopropyl trimethoxy silane, N-2-(aminoethyl)-3-aminopropyl triethoxy silane, 3-aminopropyl trimethoxy silane, 3-aminopropyl triethoxy silane, 3-triethoxysilyl-N-(3-dimethyl-butylidene)propyl amine, N-phenyl-3-aminopropyl trimethoxy silane, an N-(vinylbenzyl)-2-aminoethyl-3-aminopropyl trimethoxy silane hydrochloride salt, 3-ureidopropyl triethoxy silane, 3-chloropropyl trimethoxy silane, 3-mercaptopropyl methyl dimethoxy silane, 3-mercaptopropyl trimethoxy silane, bis(triethoxysilyl propyl)tetrasulfide, 3-isocyanatopropyl triethoxy silane, tetramethoxy silane, tetraethoxy silane, methyl trimethoxy silane, methyl triethoxy silane, dimethyl triethoxy silane, phenyl triethoxy silane, hexamethyldisilazane, hexyl trimethoxy silane, decyl trimethoxy silane, butyl trichloro silane, cyclohexyl trichloro silane, decyl trichloro silane, dodecyl trichloro silane, octyl trichloro silane, octadecyl trichloro silane, and tetradecyl trichloro silane.

Examples of coupling agents comprising Al as a metal may include aluminum isopropylate, mono sec-butoxy aluminum diisopropylate, aluminum sec-butylate, aluminum etylate, ethylacetoacetate aluminum diisopropylate, aluminum tris(ethylacetoacetate), alkylacetoacetate aluminum diisopropylate, aluminum mono-acetylacetonate bis(ethylacetoacetate), aluminum tris(acetylacetonate), aluminum mono-isopropoxy mono-oleoxy ethylacetoacetate, cyclic aluminum oxide isopropylate, cyclic aluminum oxide octylate, and cyclic aluminum oxide stearate.

Examples of coupling agents comprising Ti as a metal may include tetraisopropyl titanate, tetra-normal-butyl titanate, butyl titanate dimer, tetra(2-ethylhexyl) titanate, tetramethyl titanate, titanium acetylacetonate, titanium tetra-acetylacetonate, titanium ethylacetoacetate, titanium octane diolate, titanium lactate, titanium triethanolaminate, and polyhydroxy titanium stearate.

Examples of the thiol compounds may include octadecanethiol, azophenoxydodecanethiol, perfluoro-octylpentanethiol, butanethiol, hexanethiol, octanethiol, and dodecanethiol. When the first electrode 20 is made of oxides such as ITO, use of the coupling agent is preferable.

The step of forming the lyophobic pattern 30a may be a step in which a fluorinated lyophobic region 30 is firstly formed by steaming treatment using one or more substances selected from the group consisting of CF₄, NF₃, and a mixture of CF₄ and methanol, and subsequently the lyophobic region 30 is patterned.

Also, the lyophobic pattern 30a may directly be formed on the substrate on which the first electrode 20 is provided by, for example, an ink-jet method. In this case, the step of forming the lyophobic region 30 and the step of patterning the lyophobic region 30 are unnecessary.

As shown in FIG. 4, subsequently, a coating liquid that is repelled by the lyophobic pattern 30a is applied to the entire surface of the substrate 10 on which the lyophobic pattern 30a is formed. Thereby, a first charge transport layer 40 having a first exposure part X that exposes the lyophobic pattern 30a is formed.

As shown in FIG. 5, subsequently, an active layer 50 that covers over the first charge transport layer 40 is formed.

Also for the step of forming the active layer 50, the active layer 50 is formed by applying the coating liquid that is repelled by the lyophobic pattern 30a to the entire surface of the substrate 10 on which the lyophobic pattern 30a is formed.

As shown in FIG. 6, further, a second charge transport layer 60 that covers over the active layer 50 is formed. Also for the step of forming the second charge transport layer 60, the second charge transport layer 60 is formed by applying the coating liquid that is repelled by the lyophobic pattern 30a to the entire surface of the substrate 10 on which the lyophobic pattern 30a is formed.

By the above-described steps, in a region out of the lyophobic pattern 30a, a layered structure of the first charge transport layer 40, the active layer 50 and the second charge transport layer 60 that have island shapes is formed in a self-aligning manner, and a first exposure region X that exposes the lyophobic pattern 30a is formed.

As shown in FIG. 7, a second exposure region Y in which a part of the first electrode 20 located out of the lyophobic pattern 30a is exposed, configured to pass through the first charge transport layer 40, the active layer 50 and the second charge transport layer 60.

As shown in FIG. 8, subsequently, a second electrode 70 that covers over the second charge transport layer 60, contacts to the first electrode 20 by embedding the second exposure region Y, and does not cover the lyophobic pattern 30a. Also in the step, the second electrode 70 is formed by applying the coating liquid that is repelled by the lyophobic pattern 30a. By this step, a clearance between the lyophobic pattern 30a and the second electrode 70 is generated. A part of the second electrode into which the second exposure region Y is embedded functions as a contact 70a (an electrode) conducting the first electrode 20 and the second electrode 70.

When the second electrode 70 is formed by not a coating method but a method such as an evaporation method, the contact is formed just over the lyophobic pattern 30a without any necessity of forming the second exposure region Y because the material of the second electrode 70 is also deposited on the lyophobic pattern 30a. Therefore, the second exposure region Y may not be required to be formed in this case.

As described above, a shape of the second exposure region Y is not particularly limited because the second exposure region Y is a contact groove or a contact hole for conducting the first electrode 20 and the second electrode 70. For example, the second exposure region Y can be formed as a groove shape or a column shape such as a cylindrical shape.

The adjacent organic photovoltaic cells are electrically connected with each other by forming the contact 70a as described above. Thereby, the organic thin film solar cell module in which a plurality of organic photovoltaic cells are connected with each other is manufactured.

As described above, the first charge transport layer 40, the active layer 50, the second charge transport layer 60 and the second electrode 70 are formed by a method for forming the films in which the coating liquid, that is a solution is applied, and the applied and formed layers are dried in preferable conditions for the material and the solvent under any preferable atmosphere such as a nitrogen gas atmosphere.

As methods for forming the film, coating methods including a spin coating method, a casting method, a microgravure coating method, a gravure coating method, a bar coating method, a roll coating method, a wire-bar coating method, a dip coating method, a spray coating method, a screen printing method, a gravure printing method, a flexographic printing method, an offset printing method, an ink-jet printing method, a dispenser printing method, a nozzle coating method, and a capillary coating method may be used. The spin coating method, the flexographic printing method, the gravure printing method, the ink-jet printing method, and the dispenser printing method are preferable.

Solvent used for these methods for forming the film that use the solution is not particularly limited as long as the solvent dissolves materials of each layer, is repelled by the lyophobic pattern and is not wetly spread on the lyophobic pattern.

Examples of such solvents may include unsaturated hydrocarbon-based solvents such as toluene, xylene, mesitylene, tetralin, decalin, bicyclohexyl, butylbenzene, sec-butylbenzene, and tert-butylbenzene; halogenated saturated hydrocarbon-based solvents such as carbon tetrachloride, chloroform, dichloromethane, dichloroethane, chlorobutane, bromobutane, chloropentane, bromopentane, chlorohexane, bromohexane, chlorocyclohexane, and bromocyclohexane; halogenated unsaturated hydrocarbon-based solvents such as chlorobenzene, dichlorobenzene, and trichlorobenzene; and ether-based solvents such as tetrahydrofuran and tetrahydropyran.

As shown in FIG. 9, a third exposure region Z in which a part of the first charge transport layer 40 located out of the lyophobic pattern 30a is exposed, configured to pass through the second electrode 70, the second charge transport layer 60, and the active layer 50.

The third exposure region Z can be formed by an existing ordinary known patterning step such as a photolithography step and a subsequent etching step, and a cutting step using a rotary blade.

The third exposure region Z is a constituent for electrically isolating a first organic photovoltaic cell 100A1 and a second organic photovoltaic cell 100A2 by a region between cells 100B. By forming the third exposure region Z, a plurality of organic photovoltaic cells are formed by isolation. The region between cells 100B is a linear groove shape. In this example, the region between cells 100B isolates adjacent cells along a circumference shape (a linear shape in this example) close to a circumferential part of the first electrode. The region between cells 100B is preferably a region as small as possible, because the region does not function as a photovoltaic cell. Therefore, the third exposure region Z is preferably formed in a shape and arranged position in which a size of the region between cells 100B can be as small as possible. For example, the region between cells 100B may be constituted as close as possible to the circumferential part of the first electrode, and as a linear groove having a width as narrow as possible in this example.

### Second Embodiment

A method for manufacturing an organic thin film solar cell module according to the second embodiment in which a plurality of organic photovoltaic cells comprising a pair of electrodes comprising a first electrode and a second electrode and an active layer that is placed between the pair of electrodes are arranged on a substrate comprises: forming the first electrodes on the substrate; and forming a lyophobic pattern on the substrate out of the first electrodes provided on the substrate.

More specifically, forming the lyophobic pattern comprises removing the lyophobic region from the surface of the first electrodes by the lyophilic treatment to the entire surface of the substrate using difference between bond strength between a material comprised in the substrate and a material comprised in the lyophobic part and bond strength between a material comprised in the first electrode and a material comprised in the lyophobic region and leaving the material comprised in the lyophobic region in a region where the first electrodes are not formed in the surface of the substrate, thus forming the lyophobic pattern.

With reference to from FIG. 10 to FIG. 18, the method for manufacturing the organic thin film solar cell module according to the second embodiment is specifically described. For common steps to the first embodiment as already described, detailed description of conditions and the like may be omitted.

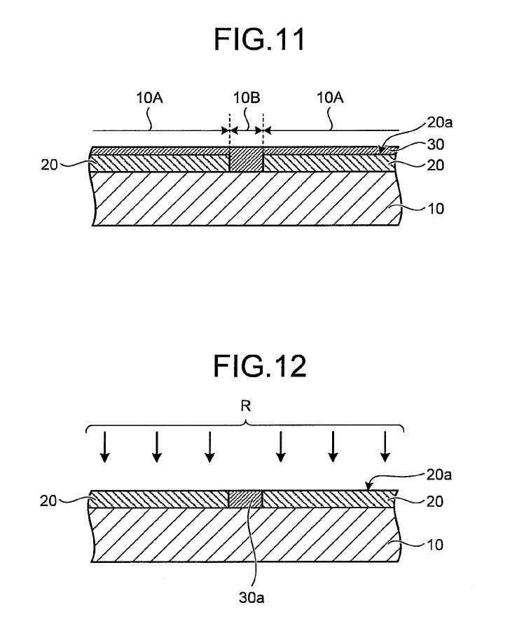

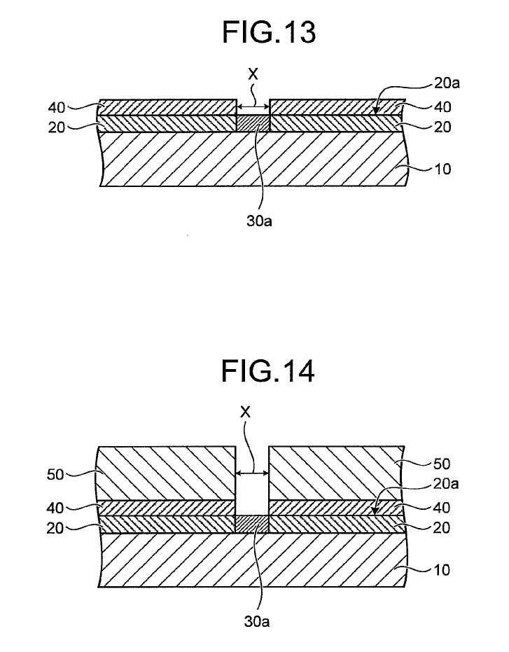

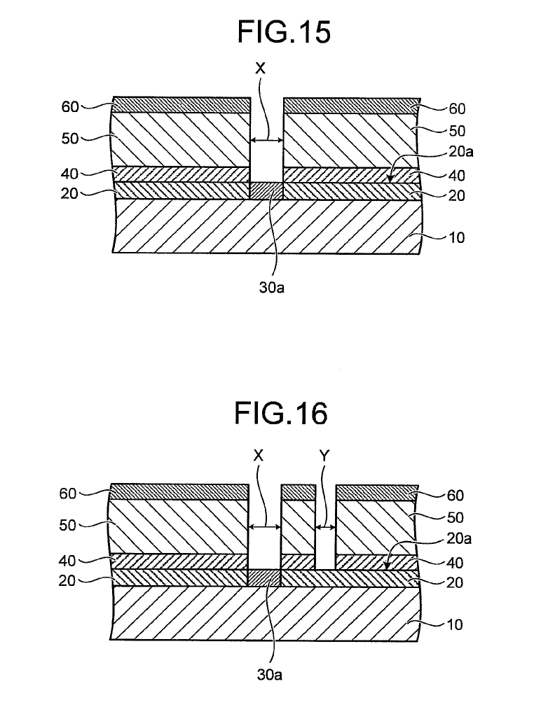

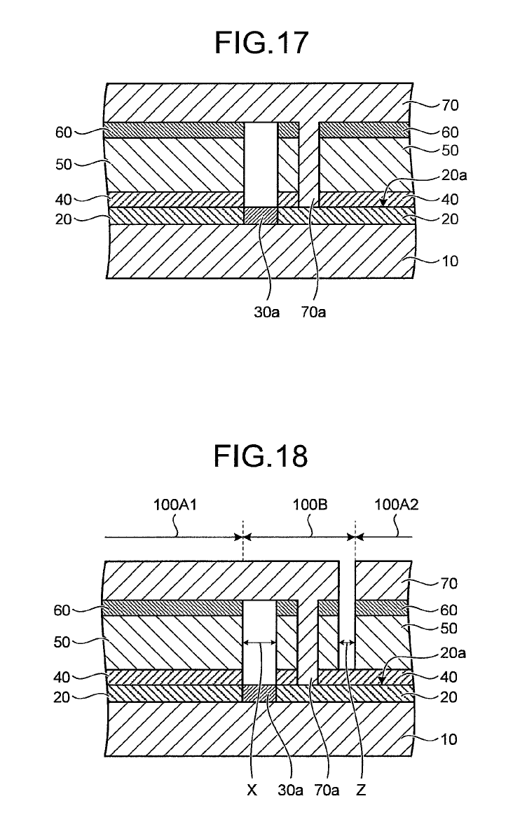

FIG. 10 is a schematic cross-sectional view (1) illustrating the method for manufacturing according to the second embodiment. FIG. 11 is a schematic cross-sectional view (2) illustrating the method for manufacturing according to the second embodiment. FIG. 12 is a schematic cross-sectional view (3) illustrating the method for manufacturing according to the second embodiment. FIG. 13 is a schematic cross-sectional view (4) illustrating the method for manufacturing according to the second embodiment. FIG. 14 is a schematic cross-sectional view (5) illustrating the method for manufacturing according to the second embodiment. FIG. 15 is a schematic cross-sectional view (6) illustrating the method for manufacturing according to the second embodiment. FIG. 16 is a schematic cross-sectional view (7) illustrating the method for manufacturing according to the second embodiment. FIG. 17 is a schematic cross-sectional view (8) illustrating the method for manufacturing according to the second embodiment. FIG. 18 is a schematic cross-sectional view (9) illustrating the method for manufacturing according to the second embodiment.

As shown in FIG. 10, a substrate 10 is firstly prepared. When a conductive material thin film is not provided on the substrate 10, the conductive material film is formed by any preferable method. Subsequently, the conductive material thin film is patterned. At this patterning, an electrode forming region 10A and an electrode non-forming region 10B located out of the electrode forming region 10A are previously set. The conductive material thin film is patterned to form a first electrode 20 that is formed by a plurality of patterns electrically separated each other in the electrode forming region 10A. In this step, a part of the main surface of the substrate 10 is exposed in the electrode non-forming region 10B.

As shown in FIG. 11, a lyophobic region 30 having lyophobicity is formed on the entire surface of the substrate 10 on which the first electrode 20 comprising the surface 20a of the first electrode 20 is formed.

The step for forming the lyophobic region 30 may be performed in a similar manner to the first embodiment. Preferably, the lyophobic region 30 may be formed using a coupling agent comprising one metal selected from the group consisting of silicon, aluminum, and titanium.

The step for forming the lyophobic region 30 may be a step in which a fluorinated lyophobic region 30 is formed by steaming treatment using one or more substances selected from the group consisting of CF₄, NF₃, and a mixture of CF₄ and methanol.

As shown in FIG. 12, the entire surface of the substrate 10 on which the first electrode 20 is formed is made lyophilic by lyophilic treatment R. Providing lyophilicity may be performed in a similar manner to the first embodiment. The lyophilic treatment R may be preferably plasma treatment, UV ozone treatment, corona discharge treatment and water washing treatment in accordance with ordinary procedures. By this step, the exposed surface of the first electrode 20, that is, the electrode forming region 10A is made lyophilic and the lyophobic pattern 30a remains only in the electrode non-forming region 10B exposed from the first electrode 20.

As described above, the second embodiment can be performed by using a surface property of the first electrode 20 (a property of a material comprised in the first electrode 20) and a surface property of the substrate 10 exposed from the first electrode 20 (a property of a material comprised in the substrate), that is, difference of removing speed by the lyophilic treatment R of a material of the lyophobic region 30 that is formed on both of the surface of the first electrode 20 and a part (a region) of the surface of the substrate 10 on which the first electrode 20 is not formed.

For example, when the fluorine treated lyophobic region 30 by CF₄ plasma treatment is washed with water in an adequate level, only fluorides that are fluorine ingredients on the first electrode 20 can be selectively removed. As a result, the lyophobic pattern 30a can be formed (can remain) in a region out of the first electrode 20.

When the steps described above are performed, a step of forming a mask pattern, a step of pattering using the mask pattern as a mask and a step of removing the mask pattern are unnecessary.

It goes without saying that the lyophobic region 30a can be formed by using the mask pattern or formed by the ink-jet method, as described in the first embodiment.

As shown in FIG. 13, subsequently, a coating liquid that is repelled by the lyophobic pattern 30a is applied to the entire surface of the substrate 10 on which the lyophobic pattern 30a is formed. Thereby, a first charge transport layer 40 having a first exposure region X that exposes the lyophobic pattern 30a is formed.

As shown in FIG. 14, subsequently, the active layer 50 that covers over the first charge transport layer 40 is formed. Also for the step of forming the active layer 50, the active layer 50 is formed by applying the coating liquid that is repelled by the lyophobic pattern 30a to the entire surface of the substrate 10 on which the lyophobic pattern 30a is formed.

As shown in FIG. 15, further, a second charge transport layer 60 that covers over the active layer 50 is formed. Also for the step of forming the second charge transport layer 60, the second charge transport layer 60 is formed by applying the coating liquid that is repelled by the lyophobic pattern 30a to the entire surface of the substrate 10 on which the lyophobic pattern 30a is formed.

By the above-described steps, in a region out of the lyophobic pattern 30a, a layered structure of the first charge transport layer 40, the active layer 50 and the second charge transport layer 60 that have island shapes is formed in a self-aligning manner, and the first exposure region X that exposes the lyophobic pattern 30a is formed.

As shown in FIG. 16, a second exposure region Y in which a part of the first electrode 20 located out of the lyophobic pattern 30a is exposed, configured to pass through the first charge transport layer 40, the active layer 50 and the second charge transport layer 60.

As shown in FIG. 17, subsequently, a second electrode 70 that covers over the second charge transport layer 60, contacts to the first electrode 20 by embedding the second exposure region Y, and does not cover the lyophobic pattern 30a. Also in the step, the second electrode 70 is formed by applying the coating liquid that is repelled by the lyophobic pattern 30a.

A part of the second electrode into which the second exposure region Y is embedded functions as a contact 70a conducting the first electrode 20 and the second electrode 70.

When the second electrode 70 is formed by not a coating method but a method such as an evaporation method, the contact is formed just over the lyophobic pattern 30a without any necessity of forming the second exposure region Y because the material of the second electrode 70 is also deposited on the lyophobic pattern 30a. Therefore, the second exposure region Y may not be required to be formed in this case.

As described above, a shape of the second exposure region Y is not particularly limited because the second exposure region Y is a contact groove for conducting the first electrode 20 and the second electrode 70. For example, the second exposure region Y can be formed as a groove shape or a hole shape.

As shown in FIG. 18, a third exposure region Z in which a part of the first charge transport layer 40 located out of the lyophobic pattern 30a is exposed, configured to pass through the second electrode 70, the second charge transport layer 60 and the active layer 50.

<Organic Photovoltaic Cell>

Here, the organic photovoltaic cell comprised in the organic thin film solar cell module manufactured by the method for manufacturing according to the present invention is described with reference to FIG. 9.

The organic photovoltaic cell comprises a pair of electrodes made of an anode and a cathode and an active layer placed between the pair of electrodes.

Among the pair of electrodes, at least one electrode into which light is incident, that is, at least one of the electrodes is a transparent or semitransparent electrode that can transmits incident light (sunlight) having a wavelength required for power generation.

As shown in FIG. 9, the organic photovoltaic cells (the first cell 100A1 and the second cell 100A2) comprise a pair of electrodes made of, for example, the first electrode 20 being an anode and the second electrode 70 being a cathode, and the active layer 50 placed between the pair of electrodes. The polarity of the first electrode 20 and the second electrode 70 may be any preferable polarity corresponding to a cell structure. It is also possible that the first electrode 20 is an anode and the second electrode 70 is an anode.

Examples of the transparent or semitransparent electrodes may include a conductive metal oxide film and a semitransparent thin metal film. Specifically, films made of conductive material such as indium oxide, zinc oxide, tin oxide and indium-tin oxide and indium-zinc oxide (IZO) that are mixed materials thereof; NESA; and films made of gold, platinum, silver, copper, and the like are used as the electrodes. Films of ITO, indium-zinc oxide and tin oxide are preferable. Examples of methods for preparing the electrode may include a vacuum evaporation method, a sputtering method, an ion plating method and a plating method. As the electrode, organic transparent conductive films such as polyaniline and a derivative thereof and polythiophene and a derivative thereof may be used.

As electrode material for an opaque electrode, metals, conductive macromolecules and the like can be used. Specific examples of the electrode material for the opaque electrode may include metals such as lithium, sodium, potassium, rubidium, cesium, magnesium, calcium, strontium, barium, aluminum, scandium, vanadium, zinc, yttrium, indium, cerium, samarium, europium, terbium and ytterbium; and alloys made of two or more of these metals, or alloys made of one or more metals and one or more metals selected from the group consisting of gold, silver, platinum, copper, manganese, titanium, cobalt, nickel, tungsten and tin; graphite, intercalation graphite compound, polyaniline and a derivative thereof, and polythiophene and a derivative thereof. Examples of the alloys may include a magnesium-silver alloy, a magnesium-indium alloy, a magnesium-aluminum alloy, an indium-silver alloy, a lithium-aluminum alloy, a lithium-magnesium alloy, a lithium-indium alloy, and a calcium-aluminum alloy.

The organic photovoltaic cell is generally formed on a substrate. In other words, the first cell 100A1 and the second cell 100A2 are provided on the main surface of the substrate 10.

A material for the substrate 10 may be any material that is not chemically changed when the electrode is formed and a layer comprising an organic material is formed. Examples of the material for the substrate 10 may include a glass, a plastic, a macromolecule film, and silicon.

When the substrate 10 is opaque, that is, the substrate does not transmit incident light, the second electrode 70 that faces the first electrode 20 and is provided on the opposite side of the substrate side (in other words, the electrode that is further from the substrate 10) is preferably a transparent electrode or a semitransparent electrode that can transmits necessary incident light.

The active layer 50 is placed between the first electrode 20 and the second electrode 70. The active layer 50 according to the second embodiment is a bulk hetero type organic layer comprising an electron acceptor compound (an n-type semiconductor) and an electron donor compound (a p-type semiconductor) in a mixed manner. The active layer has an essential function for photoelectric conversion function that can generate charges (holes and electrons) using incident light energy.

As described above, the active layer comprised in the organic photovoltaic cell comprises the electron donor compound and the electron acceptor compound.

The electron donor compound and the electron acceptor compound are relatively determined by energy level of these compounds. Therefore, one compound can become either the electron donor compound or the electron acceptor compound.

Examples of the electron donor compounds may include pyrazoline derivatives, arylamine derivatives, stilbene derivatives, triphenyldiamine derivatives, oligothiophene and derivatives thereof, polyvinylcarbazole and derivatives thereof, polysilane and derivatives thereof, polysiloxane derivatives having aromatic amines in the main chain or side chains thereof, polyaniline and derivatives thereof, polythiophene and derivatives thereof, polypyrrole and derivatives thereof, polyphenylene vinylene and derivatives thereof, and polythienylene vinylene and derivatives thereof.

Examples of the electron acceptor compounds may include oxadiazole derivatives, anthraquinodimethane and derivatives thereof, benzoquinone and derivatives thereof, naphthoquinone and derivatives thereof, anthraquinone and derivatives thereof, tetracyanoanthraquinodimethane and derivatives thereof, fluorenone derivatives, diphenyldicyanoethylene and derivatives thereof, diphenoquinone derivatives, metal complexes of 8-hydroxyquinoline and derivatives thereof, polyquinoline and derivatives thereof, polyquinoxaline and derivatives thereof, polyfluorene and derivatives thereof, fullerenes such as C₆₀ fullerene and derivatives thereof, phenanthrene derivatives such as bathocuproine, metal oxides such as titanium oxide, and carbon nanotubes. As the electron acceptor compounds, titanium oxide, carbon nanotubes, fullerenes and fullerene derivatives are preferable, and fullerenes and fullerene derivatives are particularly preferable.

Examples of the fullerenes may include C₆₀ fullerene, C₇₀ fullerene, C₇₆ fullerene, C₇₈ fullerene, and C₈₄ fullerene.

Examples of the fullerene derivatives may include derivatives of each of C₆₀ fullerene, C₇₀ fullerene, C₇₆ fullerene, C₇₈ fullerene, and C₈₄ fullerene. Examples of specific structures of the fullerene derivatives may include the following structures.

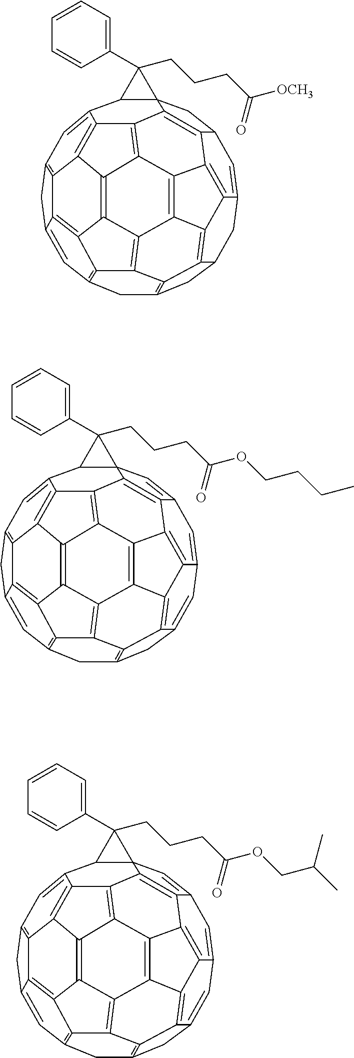

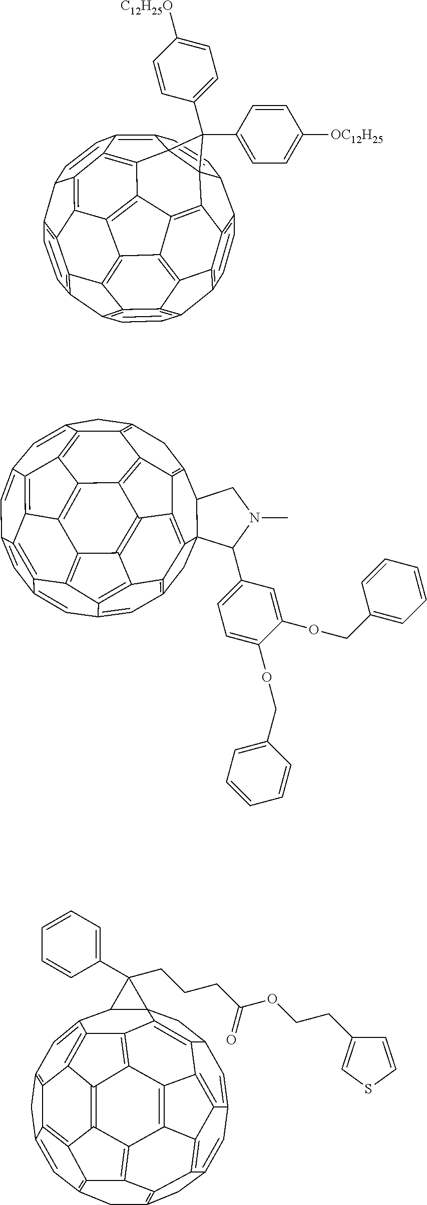

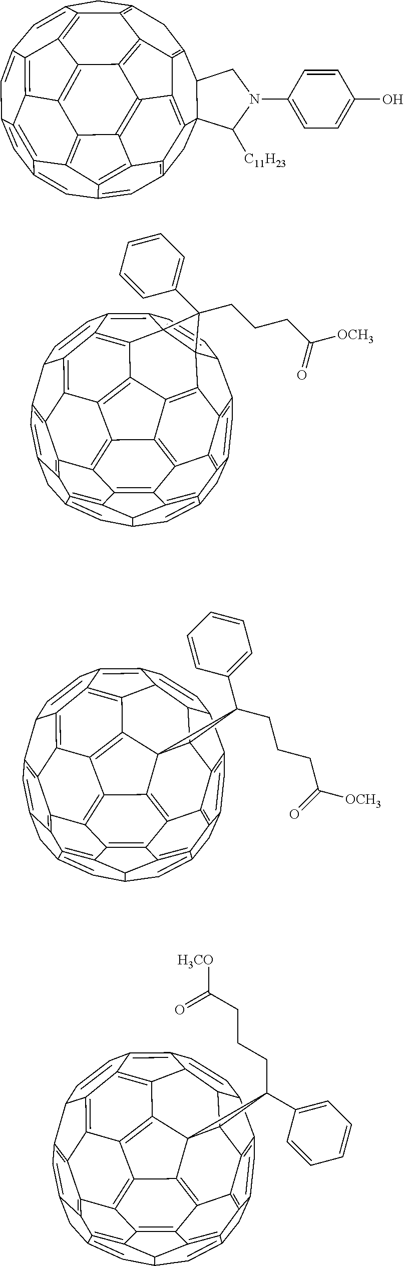

In addition, examples of the fullerene derivatives may include [6,6]-Phenyl C₆₁ butyric acid methyl ester (C₆₀PCBM), [6,6]-Phenyl C₇₁ butyric acid methyl ester (C₇₀PCMB), [6,6]-Phenyl C₈₅ butyric acid methyl ester (C₈₄PCBM), and [6,6]-Thienyl C₆₁ butyric acid methyl ester.

When the fullerene derivatives are used as the electron acceptor compounds, an amount of the fullerene derivative is preferably 10 parts by weight to 1000 parts by weight, and more preferably 20 parts by weight to 500 parts by weight per 100 parts by weight of the electron donor compound.

An amount of the electron acceptor compound in the bulk hetero type active layer comprising the electron acceptor compound and the electron donor compound is preferably 10 parts by weight to 1000 parts by weight, and more preferably 50 parts by weight to 500 parts by weight per 100 parts by weight of the electron donor compound.

A thickness of the active layer is preferably 1 nm to 100 μm, more preferably 2 nm to 1000 nm, further preferably 5 nm to 500 nm and particularly preferably 20 nm to 200 nm.

Here, an operation mechanism of the organic photovoltaic cell is simply described. Energy of incident light that transmits though the transparent or semitransparent electrode and is incident into the active layer is absorbed by the electron acceptor compound and/or the electron donor compound, and thereby exciters in which electrons and holes are combined are generated. When the generated exciters are moved and reached to a hetero-junction interface where the electron acceptor compound and the electron donor compound are joined, difference of each of HOMO energy and LUMO energy at the interface causes separation of electrons and holes and generates charges (electrons and holes) that can move independently. The generated charges can be taken out as electric energy (electric current) to out of the cell by moving the generated charges to the electrodes (the cathode and the anode).

In the organic photovoltaic cell an additional layer (in intermediate layer) other than the active layer can be provided as a means for improving photoelectric conversion efficiency between at least one electrode of the first electrode and the second electrode and the active layer. As examples of materials for the additional intermediate layer, a halide of an alkali metal and an alkaline earth metal such as lithium fluoride and an oxide of the alkali metal and the alkaline earth metal can be used. In addition, examples of materials for the additional intermediate layer may include fine particles of inorganic semiconductor such as titanium oxide, and PEDOT (poly-3,4-ethylenedioxythiophene).

Examples of the additional layer may include the charge transport layer that transports holes or electrons (a hole transport layer, an electron transport layer).

Any preferable material can be used for a material constituting the charge transport layer. When the charge transport layer is the electron transport layer, examples of the material may include 2,9-dimethyl-4,7-diphenyl-1,10-phenanthroline (BCP). When the charge transport layer is the hole transport layer, examples of the material may include PEDOT.

The intermediate layer that may be provided between the first electrode and the second electrode, and the active layer may be a buffer layer. Materials used for the buffer layer may be a halide of an alkali metal and an alkaline earth metal such as lithium fluoride, and an oxide such as titanium oxide. When an inorganic semiconductor is used, the inorganic semiconductor can be used in the form of fine particles.

Constitution of the organic photovoltaic cell is specifically described. The first electrode 20 is provided on the main surface of the substrate 10. The first charge transport layer 40 is provided on the first electrode 20. The first charge transport layer 40 is the hole transport layer when the first electrode 20 is an anode, and the electron transport layer when the first electrode 20 is a cathode.

The active layer 50 is provided on the first charge transport layer 40. The second charge transport layer 60 is provided on the active layer 50. The second charge transport layer 60 is the electron transport layer when the first electrode 20 is an anode, and the hole transport layer when the first electrode 20 is a cathode. The second electrode 70 is provided on the second charge transport layer 60.

In the organic photovoltaic cell having the above-described constitution, the single layer active layer in which the active layer 50 is the bulk hetero type that is made by mixing the electron acceptor compound and the electron donor compound is described. However, the active layer 50 may be constituted by a plurality of layers. For example, the active layer may be a hetero-junction type in which the electron acceptor layer comprising the electron acceptor compound such as the fullerene derivative and an electron donor layer comprising the electron donor compound such as P3HT are joined.

Here, one example of layer constitution in which the organic photovoltaic cell may be possible is indicated below.

a) anode/active layer/cathode
b) anode/hole transport layer/active layer/cathode
c) anode/active layer/electron transport layer/cathode
d) anode/hole transport layer/active layer/electron transport layer/cathode
e) anode/electron supplying layer/electron acceptor layer/cathode
f) anode/hole transport layer/electron supplying layer/electron acceptor layer/cathode
g) anode/electron supplying layer/electron acceptor layer/electron transport layer/cathode
h) anode/hole transport layer/electron supplying layer/electron acceptor layer/electron transport layer/cathode
(Here, the symbol “/” represents that layers sandwiching the symbol “/” are adjacently stacked each other).

The layer constitution may be either a form in which the anode is provided at the nearer side to the substrate or a form in which the cathode is provided at the nearer side to the substrate.

Each of the layers may be constituted by not only a single layer but also a layered body made of two or more layers.

### EXAMPLES

### Example 1

### Lyophobic Treatment at Electrode

After protecting with Kapton tape a side face of a polyethylene naphtholate (may be referred to as PEN) film substrate with ITO film (trade name: OTEC, manufactured by Tobi Co., Ltd) where an electrode was to be formed, the substrate was immersed into HNO₃ having a concentration of 1 mol/L for 3 minutes to pattern the ITO film to a pattern in which a plurality of electrodes (the first electrodes) were arranged and the main surface of the PEN film substrate was exposed out the electrodes. After washing the substrate in which the electrodes were patterned with acetone, UV ozone cleaning treatment was performed for 15 minutes by an ultraviolet ozone irradiation device equipped with a low-pressure mercury vapor lamp (Type: UV-312, manufactured by Technovision, Inc.) to prepare the first electrodes having a clear surface on the PEN substrate. Subsequently, after immersing the substrate on which the first electrodes were formed into a solution in which a concentration of 0.5% by weight of octadecyl trichloro silane was dissolved in an octane solvent, the substrate was heated at 120° C. for 30 minutes. Thereafter, after protecting with Kapton tape a part region on the first electrodes that became a lyophobic pattern, UV ozone treatment was performed for 15 minutes to prepare a first substrate 1 comprising the first electrodes and the lyophobic pattern.

Subsequently, PEDOT (Trade name Baytron P AI4083, Lot. HCD07O109, manufactured by Starck) that was a hole transport material was applied on the substrate 1 by a spin coating method. The patterned PEDOT layer was formed out of the lyophobic pattern by this applying step. Thereafter, the substrate 1 was dried at 150° C. for 30 minutes in the atmosphere. Subsequently, after adding poly(3-hexyl thiophene) (P3HT) (Trade name: lisicon SP001, Lot. EF431002, manufactured by Merck) as a conjugated polymer compound being an electron donor material and PCBM (Trade Name: E100, Lot. 7B0168-A, manufactured by Frontier Carbon Corporation) as a fullerene derivative being an electron acceptor material to an o-dichlorobenzene solvent so that P3HT was 1.5% by weight and PCBM was 1.2% by weight and stirring at 70° C. for 2 hours. The mixture was filtered with a filter having a pore diameter of 0.2 μm. Accordingly, a coating liquid is prepared. Subsequently, an active layer was formed by applying the coating liquid on the PEDOT layer by the spin coating method. The patterned active layer was formed out of the lyophobic pattern by this applying step.

### Example 2

### Lyophobic Treatment in a Region Out of Electrodes

After protecting with Kapton tape a side face of a PEN film substrate with ITO film (trade name: OTEC, manufactured by Tobi Co., Ltd) where a first electrode was to be formed, the substrate was immersed into HNO₃ having a concentration of 1 mol/L for 3 minutes to pattern and form the ITO film to a pattern comprising a plurality of first electrodes. After washing the substrate in which the electrodes were patterned with acetone, UV ozone cleaning treatment was performed for 15 minutes by the ultraviolet ozone irradiation device equipped with the low-pressure mercury vapor lamp (Type: UV-312, manufactured by Technovision, Inc.) to prepare the first electrodes having a clear surface on the PEN substrate.

Subsequently, after protecting the first electrodes with Kapton tape, the substrate was introduced into an atmospheric plasma device to treat with plasma under a CF₄ atmosphere. Thereafter, the Kapton tape is peeled off to obtain a second substrate 2.

Thereafter, a layered structure was formed by using the second substrate 2 by the same method as in Example 1.

### INDUSTRIAL APPLICABILITY

The present invention is useful for manufacturing an organic thin film solar cell module.

1. A method for manufacturing an organic thin film solar cell module in which a plurality of organic photovoltaic cells comprising a pair of electrodes comprising a first electrode and a second electrode and an active layer that is placed between the pair of electrodes are arranged on a substrate, the method comprising the steps of:
forming the first electrodes on the substrate; and
forming a lyophobic pattern on a part of each of the first electrodes.

2. A method for manufacturing an organic thin film solar cell module in which a plurality of organic photovoltaic cells comprising a pair of electrodes comprising a first electrode and a second electrode and an active layer that is placed between the pair of electrodes are arranged on a substrate, the method comprising the steps of:
forming the first electrodes on the substrate; and
forming a lyophobic pattern on the substrate out of the first electrodes.

3. The method for manufacturing an organic thin film solar cell module according to claim 1, wherein the step of forming the lyophobic pattern comprises:
forming a lyophobic region over an entire surface of the substrate on which the first electrodes are formed; and
forming a mask pattern covering over a part of the substrate on which the first electrodes are formed, performing lyophilic treatment using the mask pattern as a mask to the entire surface of the substrate on which the first electrodes are formed, and removing the mask pattern, thereby forming the lyophobic pattern.

4. A method for manufacturing an organic thin film solar cell module, the method comprising the steps of:
forming a plurality of first electrodes on a substrate;
forming a lyophobic region on an entire surface of the substrate on which the first electrodes are formed;
forming a lyophobic pattern by forming a mask pattern covering over a part of the substrate on which the first electrodes are formed, performing lyophilic treatment using the mask pattern as a mask to the entire surface of the substrate on which the first electrodes are formed, and removing the mask pattern;
forming a first charge transport layer comprising a first exposure part exposing the lyophobic pattern, an active layer covering over the first charge transport layer, and a second charge transport layer covering over the active layer, by applying a coating liquid that is repelled by the lyophobic pattern on the entire surface of the substrate on which the lyophobic pattern is formed;
forming a second exposure region in which a part of the first electrodes located out of the lyophobic pattern is exposed, configured to pass through the second charge transport layer, the active layer, and the first charge transport layer;
forming a second electrode by applying a coating liquid, the second electrode covering over the second charge transport layer, embedding the second exposure region, and not covering the lyophobic pattern; and
isolating a plurality of organic photovoltaic cells by forming a third exposure region in which a part of the first charge transport layer located out of the lyophobic pattern is exposed, configured to pass through the second electrode, the second charge transport layer, and the active layer.

5. The method for manufacturing an organic thin film solar cell module according to claim 4, wherein the step of forming the lyophobic pattern comprises removing the lyophobic region from the surface of the first electrodes by lyophilic treatment to the entire surface of the substrate using difference between bond strength between a material comprised in the substrate and a material comprised in the lyophobic region and bond strength between a material comprised in the first electrodes and a material comprised in the lyophobic region, and leaving the material comprised in the lyophobic region in a region where the first electrodes are not formed in the surface of the substrate, thus forming the lyophobic pattern.

6. The method for manufacturing an organic thin film solar cell module according to claim 1, wherein the step of forming the lyophobic pattern comprises forming the lyophobic pattern using a coupling agent comprising one metal selected from the group consisting of silicon, aluminum, and titanium.

7. The method for manufacturing an organic thin film solar cell module according to claim 1, wherein the step of forming the lyophobic pattern comprises forming the lyophobic pattern using a material comprising a thiol compound.

8. The method for manufacturing an organic thin film solar cell module according to claim 1, wherein the step of forming the lyophobic pattern comprises forming the lyophobic pattern using a material comprising fluorine.

9. The method for manufacturing an organic thin film solar cell module according to claim 8, wherein the step of forming the lyophobic pattern comprises forming the lyophobic pattern by steaming treatment using one or more selected from the group consisting of CF₄, NF₃, and a mixture of CF₄ and methanol.

10. An organic thin film solar cell module that is manufactured by the method for manufacturing according to claim 1.

11. The method for manufacturing an organic thin film solar cell module according to claim 4, wherein the step of forming the lyophobic pattern comprises forming the lyophobic pattern using a coupling agent comprising one metal selected from the group consisting of silicon, aluminum, and titanium.

12. The method for manufacturing an organic thin film solar cell module according to claim 4, wherein the step of forming the lyophobic pattern comprises forming the lyophobic pattern using a material comprising a thiol compound.

13. The method for manufacturing an organic thin film solar cell module according to claim 4, wherein the step of forming the lyophobic pattern comprises forming the lyophobic pattern using a material comprising fluorine.

14. The method for manufacturing an organic thin film solar cell module according to claim 13, wherein the step of forming the lyophobic pattern comprises forming the lyophobic pattern by steaming treatment using one or more selected from the group consisting of CF₄, NF₃, and a mixture of CF₄ and methanol.

15. An organic thin film solar cell module that is manufactured by the method for manufacturing according to claim 4.
